(19) United States
(12) Patent Application Publication
(10) Pub. No.: US 2021/0118778 A1
(43) Pub. Date: Apr. 22, 2021

(54) SEMICONDUCTOR PACKAGE HAVING A LEAD FRAME AND A HEAT-SINK LEAD FRAME

(71) Applicant: SEMICONDUCTOR COMPONENTS INDUSTRIES, LLC, Phoenix, AZ (US)

(72) Inventor: Eddy Alberic Joseph BLANSAER, Oostakker (BE)

(73) Assignee: SEMICONDUCTOR COMPONENTS INDUSTRIES, LLC, Phoenix, AZ (US)

(21) Appl. No.: 16/658,421

(22) Filed: Oct. 21, 2019

(51) Int. Cl. H01L 23/495; H01L 23/498; H01L 23/00

(52) U.S. Cl. CPC H01L 23/49568; H01L 23/49541; H01L 24/48; H01L 24/32; H01L 23/49861

(57) ABSTRACT

According to an aspect, a semiconductor package includes a semiconductor die having a first surface and a second surface opposite to the first surface, a lead frame coupled to the second surface of the semiconductor die, and a heat-sink lead frame coupled to the first surface of the semiconductor die, where the semiconductor die is disposed between the lead frame and the heat-sink lead frame, and the heat-sink lead frame is configured to transfer heat away from the semiconductor die.

### TECHNICAL FIELD

This description relates to a semiconductor package with a lead frame and a heat-sink lead frame.

### BACKGROUND

In some conventional approaches, a semiconductor package is coupled to a printed circuit board, and a heat sink may be attached to a bottom side of the printed circuit board to transfer heat away from one or more electrical components in the semiconductor package.

### SUMMARY

According to an aspect, a semiconductor package includes a semiconductor die having a first surface and a second surface opposite to the first surface, a lead frame coupled to the second surface of the semiconductor die, and a heat-sink lead frame coupled to the first surface of the semiconductor die, where the semiconductor die is disposed between the lead frame and the heat-sink lead frame, and the heat-sink lead frame is configured to transfer heat away from the semiconductor die.

According to some aspects, the semiconductor package may include one or more of the following features (or any combination thereof). The heat-sink lead frame may include a plurality of tie bars connected to the lead frame. The semiconductor package may include a molding encapsulating the semiconductor die, where at least a portion of the heat-sink lead frame is exposed outside of the molding. The lead frame may include a die paddle and a plurality of leads configured to connect with an external device, where the heat-sink lead frame is devoid of leads. The semiconductor package may include a first adhesive layer coupled to the lead frame, and a second adhesive layer coupled to the heat-sink lead frame. The heat-sink lead frame may include an upper ring pad, a central contact pad, and a plurality of connecting members connecting the upper ring pad to the central contact pad. The central contact pad may be coupled to the first surface of the semiconductor die. The upper ring pad may be disposed in a first plane and the central contact may be disposed in a second plane, where the first plane is disposed a distance away from the second plane, and the plurality of connecting members extend between the first plane and the second plane. The upper ring pad has a sidewall defining an opening, and the plurality of connecting members are coupled to the sidewall. The heat-sink lead frame may include a first tie bar extending from a first corner portion of the upper ring pad, and a second tie bar extending from a second corner portion of the upper ring pad.

According to an aspect, a semiconductor package includes a semiconductor die having a first surface and a second surface opposite to the first surface, and a lead frame coupled to the second surface of the semiconductor die, where the lead frame includes a plurality of leads and a plurality of first tie bars, and the plurality of leads is configured to connect to an external device. The semiconductor package includes a heat-sink lead frame coupled to the first surface of the semiconductor die, where the heat-sink lead frame includes a plurality of second tie bars, the plurality of second tie bars are coupled to the plurality of first tie bars, and the heat-sink lead frame is configured to transfer heat way from the semiconductor die.

According to some aspects, the semiconductor package may include one or more of the above/below features (or any combination thereof). The heat-sink lead frame may include an upper ring pad, a central contact pad, and a plurality of connecting members connecting the upper ring pad to the central contact pad, where the central contact pad is coupled to the first surface of the semiconductor die. The upper ring pad is disposed in a first plane and the central contact pad is disposed in a second plane, where the first plane is disposed a distance away from the second plane, and the plurality of connecting members extend between the first plane and the second plane. The upper ring pad has a sidewall defining an opening, and the plurality of connecting members are coupled to the sidewall. The semiconductor package may include a molding encapsulating the central contact pad and the plurality of connecting member, where at least a portion of the upper ring pad is exposed through the molding, and at least a portion of the lead frame is exposed through the molding. The lead frame may include a die paddle coupled to the semiconductor die, where the die paddle has a size that is substantially the same as a size of the upper ring contact. The semiconductor package may include a bond wire having a first end portion and a second end portion, where the first end portion of the bond wire is connected to one of the plurality of leads of the lead frame, and the second end portion of the bond wire is connected to the first surface of the semiconductor die. The semiconductor die may be connected to the lead frame in a flip-chip configuration.

According to an aspect, a method of fabricating a semiconductor package having dual lead frames includes disposing a lead frame assembly in a cavity of a mold chase, where the lead frame assembly includes a lead frame strip having a lead frame, and the lead frame assembly includes a semiconductor die having a first surface coupled to the lead frame. The method includes disposing a heat-sink lead frame strip in the cavity of the mold chase, where the heat-sink lead frame strip includes a heat-sink lead frame having an upper ring pad, a central contact pad, and a plurality of connecting members connecting the upper ring pad to the central contact pad. The method includes injecting a molding material into the cavity of the mold tool. In some examples, at least a portion of the upper ring pad is exposed through the molding, and at least a portion of the first lead frame is exposed through the molding.

The details of one or more implementations are set forth in the accompanying drawings and the description below. Other features will be apparent from the description and drawings, and from the claims.

### BRIEF DESCRIPTION OF THE DRAWINGS

FIG. 1A illustrates a semiconductor package according to an aspect.

FIG. 1B illustrates a side view of a semiconductor package according to another aspect.

FIG. 1C illustrates a perspective of the semiconductor package according to an aspect.

FIG. 1D illustrates a side view of the semiconductor package according to another aspect.

FIG. 1E illustrates a top view of a heat-sink lead frame according to an aspect.

FIG. 1F illustrates a top view of a lead frame according to an aspect.

FIG. 1G illustrates a perspective of a semiconductor package depicting portions of the heat-sink lead frame and portions of the lead frame exposed through the molding according to an aspect.

FIG. 1H illustrates a top view of the semiconductor package depicting a portion of the heat-sink lead frame exposed through the molding according to an aspect.

FIG. 1I illustrates a bottom view of the semiconductor package depicting portions of the lead frame exposed through the molding according to an aspect.

FIG. 1J illustrates a side view of the semiconductor package according to an aspect.

FIG. 2 illustrates a semiconductor product having a semiconductor package according to an aspect.

FIG. 3 illustrates a semiconductor product having a semiconductor package according to an aspect.

FIG. 4 illustrates a process flow for manufacturing a semiconductor package according to an aspect.

FIG. 5A illustrates a lead frame assembly used for manufacturing a plurality of semiconductor packages according to an aspect.

FIG. 5B illustrates an enlarged view of a portion of the lead frame assembly according to an aspect.

FIG. 6A illustrates a heat-sink lead frame assembly used for manufacturing a plurality of semiconductor packages according to an aspect.

FIG. 6B illustrates an enlarged view of a portion of the heat-sink lead frame assembly according to an aspect.

FIG. 6C illustrates a side view of the portion of the heat-sink lead frame assembly according to an aspect.

FIGS. 7A through 7J illustrates various aspects of a manufacturing process according to an aspect.

### DETAILED DESCRIPTION

The present disclosure relates to a semiconductor package having a semiconductor die, a heat-sink lead frame coupled to a first surface (e.g., a top surface) of the semiconductor die, a lead frame coupled to a second surface (e.g., a bottom surface) of the semiconductor die, and a molding that encapsulates the semiconductor die. The lead frame has a portion that is exposed outside of the molding (thereby providing an exposed conductive pad on the bottom of the semiconductor package), and the heat-sink lead frame has a portion that is exposed outside of the molding (thereby providing an exposed conductive pad on the top of the semiconductor package). The heat-sink lead frame may reduce the overall thermal resistance of the semiconductor package, thereby allowing higher heat dissipation. In some examples, the dual exposed pads (e.g. one on the top of the semiconductor package, and one on the bottom of the semiconductor package) may provide a dual cooling option that increases the cooling of the semiconductor package within its application. In some examples, the exposed lead frame is configured to be coupled to a substrate (e.g., a printed circuit board (PCB)), and the exposed heat-sink lead frame is configured to be coupled to a heat sink, thereby providing a dual cooling option on the top and bottom sides of the semiconductor package. In addition, for top-side cooling, one or more components may be placed on one or both sides of the substrate (e.g., a PCB substrate), thereby allowing smaller and more cost-effective applications.

The heat-sink lead frame is formed from a lead frame. For example, a lead frame strip may be processed (e.g., chemically etched and/or mechanically punched) to create individual heat-sink lead frames. In some examples, the heat-sink lead frame includes an upper ring pad, a central contact pad, and a plurality of connecting members that connect the central contact pad to the upper ring pad. The central contact pad may be offset (e.g., down set) from the upper ring pad in a vertical stack direction. The central contact pad contacts the semiconductor die, and the upper ring pad has at least a portion that is exposed outside of the molding. The exposed upper ring pad and the central contact pad connected through the connecting members may provide enhanced thermal contact and heat transfer between the semiconductor die and the exposed upper ring pad. In some examples, the heat-sink lead frame includes a plurality of tie bars (that extend from the upper ring pad) that are coupled to corresponding tie bars on the lead frame, which may increase the structural reliability of the semiconductor package.

In some examples, the semiconductor die is coupled to the lead frame using die attach material, and bond wires are connected to the semiconductor die and the lead frame. In some examples, the structure of the heat-sink lead frame may provide a space (e.g., a gap, an opening) to permit the bond wires to be connected to the semiconductor die and the lead frame. In some examples, the semiconductor die is coupled to the lead frame in flip-chip configuration. The heat-sink lead frame may be placed on top of the semiconductor die, but the spring-based structure of the heat-sink lead frame may reduce the amount of force applied to the top of the semiconductor die (thereby decreasing the amount of force applied to the flip-chip connections between the semiconductor die and the lead frame) during the manufacturing of the semiconductor package.

In some examples, the dual-frame semiconductor package may decrease manufacturing complexities/costs associated with conventional packages that may require heat transfer components. For example, the manufacturing of the semiconductor package as discussed herein may be used with existing manufacturing equipment, where a heat-sink lead frame strip is loaded on top of a lead frame assembly within a cavity of a molding chase, and the molding is injected into the cavity of the molding chase. The lead frame strip and the heat-sink lead frame strip may define locator holes, where the locator holes and the down-set structure of the individual heat-sink lead frames may provide proper alignment within the cavity of the molding chase. These and other features are described in further details with respect to the figures.

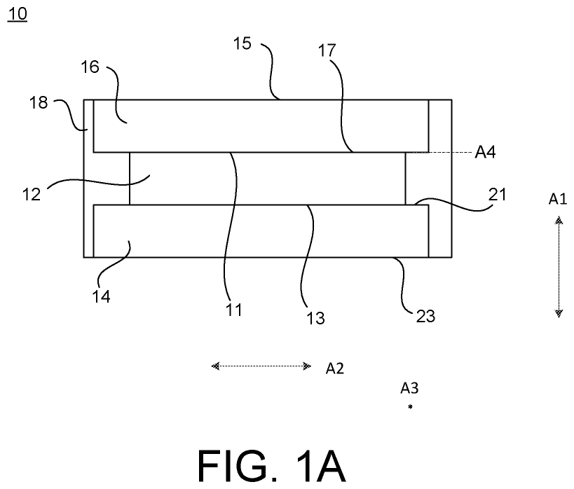

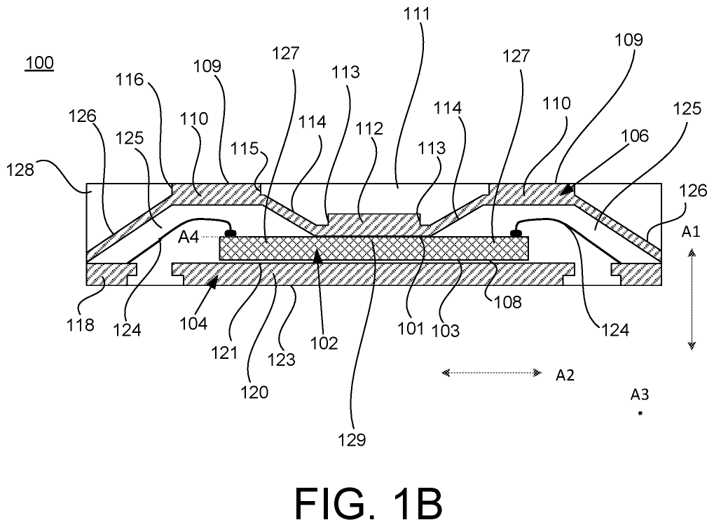

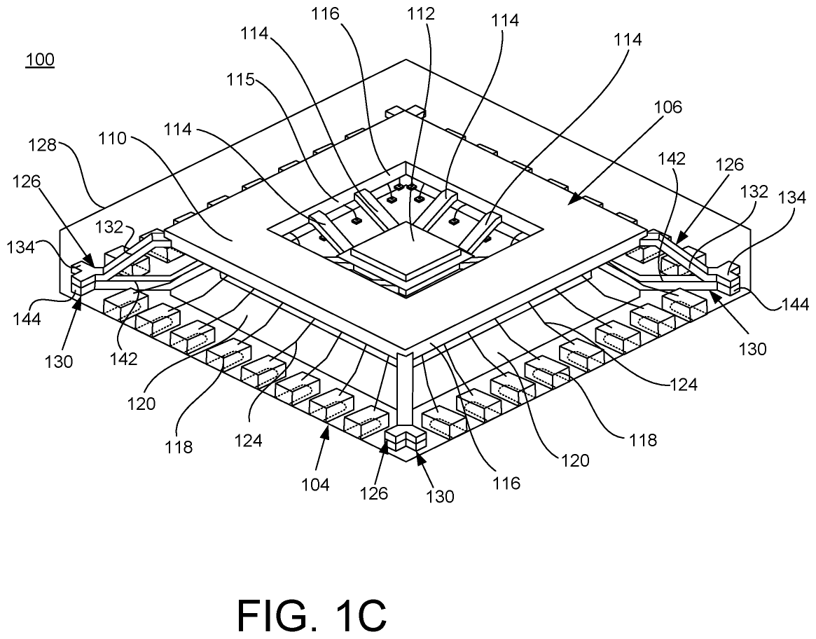

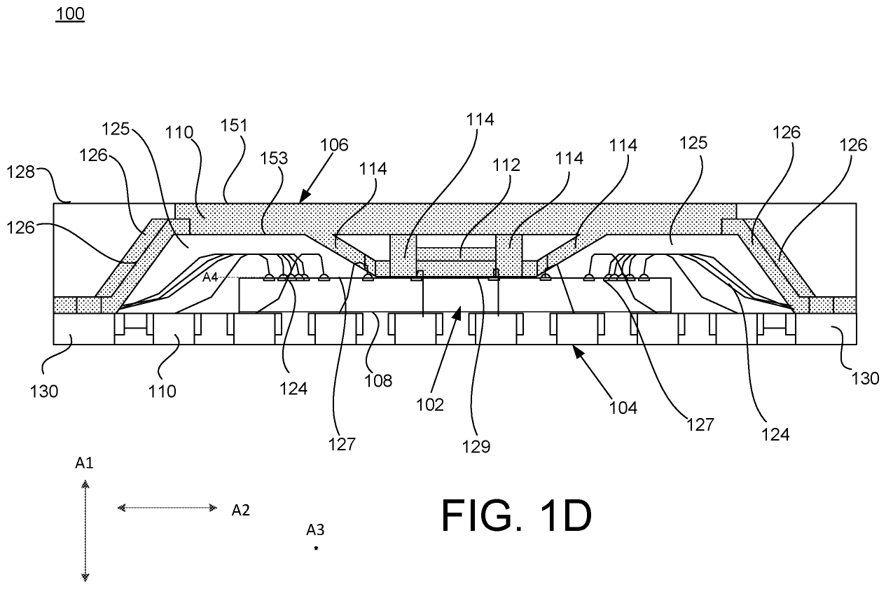

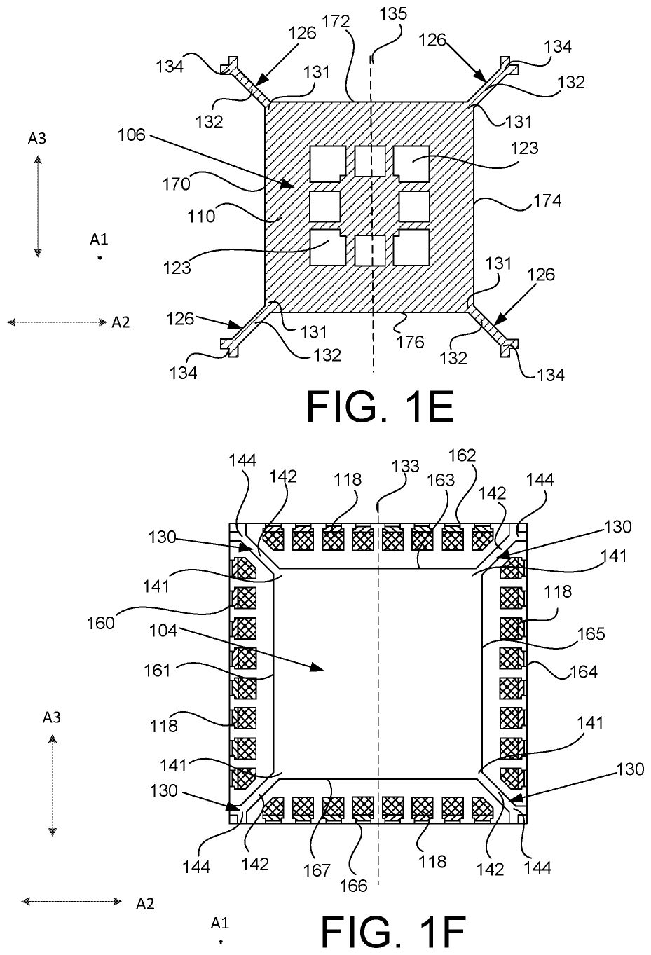

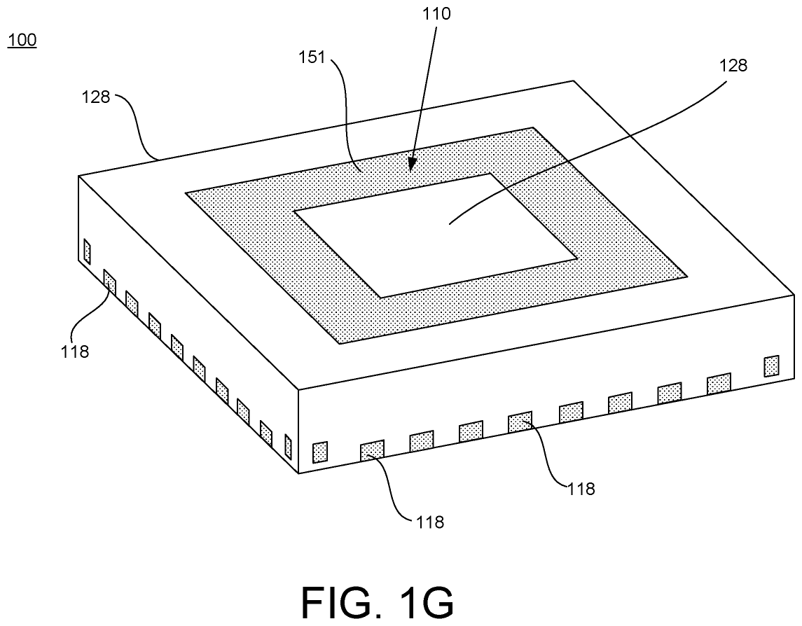

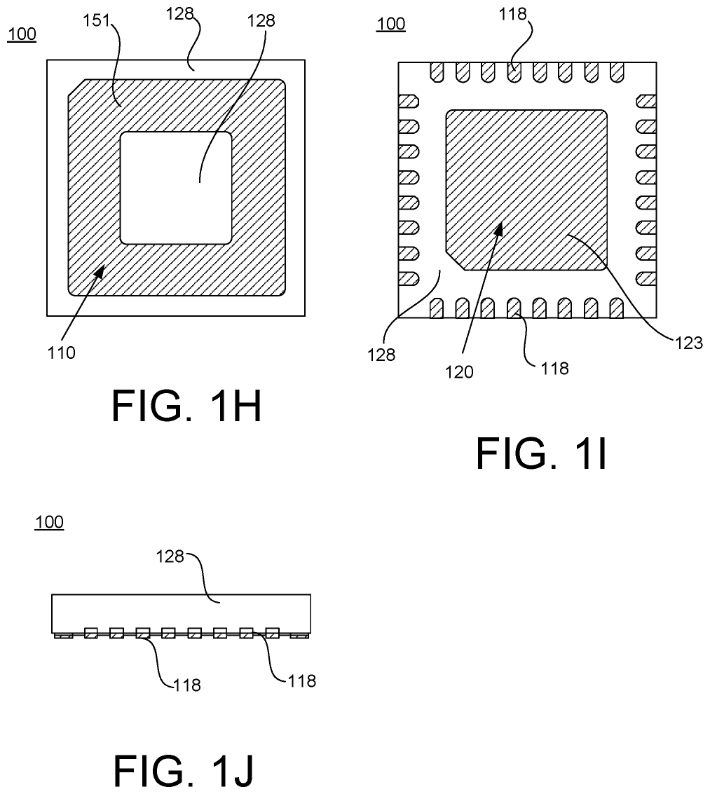

FIG. 1A illustrates a semiconductor package 10 according to an aspect. The semiconductor package 10 includes a semiconductor die 12, a lead frame 14, and a heat-sink lead frame 16. The semiconductor die 12 is disposed between the lead frame 14 and the heat-sink lead frame 16, and the heat-sink lead frame 16 is configured to transfer heat away from the semiconductor die 12 towards the top side (as oriented in this figure) of the semiconductor package 10. FIG. 1A, and the associated description, is a high-level block diagram that illustrates the concepts of this disclosure and more details of the concepts are shown and described in connection with at least FIGS. 1B through 1J.

In some examples, the heat-sink lead frame 16 includes an exposed conduction pad 15 (e.g., exposed outside of a molding 18) on a top side of the semiconductor package 10 and a central contact pad 17 coupled to the semiconductor die 12 (e.g., disposed inside of the molding 18). The heat-sink lead frame 16 may reduce the overall thermal resistance of the semiconductor package 10, thereby allowing higher heat dissipation.

In some examples, the lead frame 14 includes an exposed conduction pad (e.g., on a bottom surface of the lead frame 14), and the exposed conduction pad on the lead frame 14 in conjunction with the exposed conduction pad 15 on the lead-sink lead frame 16 may allow for dual-side cooling (e.g., away from the top of the semiconductor die 12 and away from the bottom of the semiconductor die 12).

The heat-sink lead frame 16 may be coupled to a first surface 11 (e.g., a top surface) of the semiconductor die 12, and is configured to facilitate top side cooling of the semiconductor die 12. The heat-sink lead frame 16 is a metal-based structure (e.g., copper) formed from a lead frame strip. In some examples, the heat-sink lead frame 16 has a structure modified from the structure of the lead frame 14. In some examples, a lead frame strip is processed (e.g., chemically etched and/or mechanically punched) to create the heat-sink lead frame 16.

As indicated above, the heat-sink lead frame 16 includes the exposed conduction pad 15 and the central contact pad 17. In some examples, the exposed conduction pad 15 is an exposed portion (e.g., conductive (metal) portion) of the top surface of the heat-sink lead frame 16. In some examples, the exposed conduction pad 15 and the central contact pad 17 are connected to each other via one or more connecting members (e.g., conductive (metal) portions). In some examples, the exposed conduction pad 15 and the central contact pad 17 are offset with respect to each other in a direction Al. In some examples, the structure of the heat-sink lead frame 16 not only facilitates the transfer to heat away from the semiconductor die 12 but also provides structural reliability for the semiconductor package 10. In some examples, the heat-sink lead frame 16 includes tie bars, and the tie bars of the heat-sink lead frame 16 are connected to the lead frame 14.

In some examples, the molding 18 includes an inorganic material. In some examples, the molding 18 includes an organic material. In some examples, the molding 18 includes a combination of one or more organic materials and/or one or more inorganic materials. In some examples, the molding 18 includes an epoxy material formed from epoxy resins. In some examples, the molding 18 includes a gel material (e.g., silicone gel).

In some examples, the semiconductor package 10 is a flat no-leads package. In some examples, the semiconductor package 10 is a quad flat non-leaded (QFN) package. In some examples, the semiconductor package 10 is a dual-flat no-leads (DFN) semiconductor package 10. However, the semiconductor package 10 may incorporate any type of surface-mount technology including leaded and non-leaded packages. The semiconductor die 12 includes a semiconducting material (e.g., a silicon material) on which one or more electrical circuit are fabricated. The semiconductor die 12 may include one or more transistors (e.g., bipolar junction transistor, field-effect transistor, a metal-oxide-semiconductor field-effect transistor (MOSFET)). The semiconductor die 12 may include one or more integrated circuits (ICs).

The semiconductor die 12 includes a first surface 11 and a second surface 13. The distance between the first surface 11 and the second surface 13 may define a thickness of the semiconductor die 12 in the direction A1. The first surface 11 of the semiconductor die 12 is disposed in a plane A4. The second surface 13 may be disposed in parallel with the first surface 11. The direction A1 is aligned perpendicular to the plane A4, and a direction A2 is perpendicular to the direction A1. A direction A3 into the page (shown as a dot) is aligned parallel to the plane A4 and is orthogonal to directions A1 and A2. The directions A1, A2, and A3, and plane A4, are used throughout several of the various views of the implementations described throughout the figures for simplicity.

The lead frame 14 includes a first surface 21 and a second surface 23 disposed opposite to the first surface 21. The distance between the first surface 21 and the second surface 23 may define a thickness of the lead frame 14 in the direction A1. In some examples, the lead frame 14 may include a die paddle, leads, and tie bars. In some examples, the lead frame 14 is flat or substantially flat. For example, the die paddle, the leads, and the tie bars may be aligned with each other and extend in the same plane. In some examples, the tie bars of the lead frame 14 are connected to the tie bars of the heat-sink lead frame 16. The lead frame 14 may be a conductive (metal) frame in which the semiconductor die 12 is attached. In some examples, the lead frame 14 is a copper metal frame. The second surface 13 of the semiconductor die 12 is coupled to the first surface 21 of the lead frame 14. In some examples, the second surface 23 of the lead frame 14 is coupled to a substrate (e.g., a printed circuit board (PCB). One or more portions of the lead frame 14 may be exposed outside of the molding 18. In some examples, a portion of the second surface 23 of the lead frame 14 is exposed outside of the molding 18.

The lead frame 14 is coupled to the semiconductor die 12. In some examples, the first surface 21 of the lead frame 14 is coupled to the second surface 13 of the semiconductor die 12 using die attach material (e.g., an adhesive layer, solder-based material, or other types of bonding materials). In some examples, the lead frame 14 is communicately coupled to the semiconductor die 12 using bond wires that are attached to the semiconductor die 12 and the lead frame 14. In some examples, the semiconductor die 12 is coupled to the lead frame 14 in a flip-chip configuration. For example, the semiconductor die 12 is coupled to the lead frame 14 using bump members (e.g., copper pillars) with an underfill material that encompasses the bump members. In some examples, the heat-sink lead frame 16 may be placed on top of the semiconductor die 12, but the spring-based structure of the heat-sink lead frame 16 may reduce the amount of force applied to the top of the semiconductor die 12 (thereby decreasing the amount of force applied to the flip-chip connections between the semiconductor die 12 and the lead frame 14) during the manufacturing of the semiconductor package 10.

In some examples, the semiconductor package 10 may decrease manufacturing complexities/costs associated with conventional packages that may require heat transfer components. For example, the manufacturing of the semiconductor package 10 as discussed herein may be used with existing manufacturing equipment, where a heat-sink lead frame strip having the heat-sink lead frame 16 is loaded on top of a lead frame assembly having the lead frame 14 within a cavity of a molding chase, and the molding is injected into the cavity of the molding chase. The lead frame assembly having the lead frame 14 and the heat-sink lead frame strip having the heat-sink lead frame 16 may define locator holes, where the locator holes and the down-set structure of the heat-sink lead frame 16 may provide proper alignment within the cavity of the molding chase.

FIGS. 1B through 1I illustrate a semiconductor package 100 having a semiconductor die 102, a lead frame 104 coupled to the semiconductor die 102, and a heat-sink lead frame 106 coupled to the semiconductor die 102, where the semiconductor die 102 is disposed between the lead frame 104 and the heat-sink lead frame 106. The semiconductor package 100 may include any of the features discussed with reference to the semiconductor package 10 of FIG. 1A. Also, the semiconductor package 100 includes a molding 128, where a portion of the lead frame 104 is exposed outside of the molding 128 on a bottom side of the semiconductor package 100, and a portion of the heat-sink lead frame 106 is exposed outside of the molding 128 on a top side of the semiconductor package 100. The heat-sink lead frame 106 is configured to transfer heat away from the semiconductor die 102 towards the top-side of the semiconductor package 100. For example, the heat-sink lead frame 106 may reduce the overall thermal resistance of the semiconductor package 100, thereby allowing higher heat dissipation.

FIG. 1B illustrates a side view of the semiconductor package 100 according to an aspect. FIG. 1C illustrates a perspective of the semiconductor package 100 according to an aspect. FIG. 1D illustrates a side view of the semiconductor package 100 according to another aspect. FIG. 1E illustrates a top view of the heat-sink lead frame 106 according to an aspect. FIG. 1F illustrates a top view of the lead frame 104 according to an aspect. FIG. 1G illustrates a perspective of the semiconductor package 100 depicting portions of the heat-sink lead frame 106 and portions of the lead frame 104 exposed through the molding 128 according to an aspect. FIG. 1H illustrates a top view of the semiconductor package 100 depicting a portion of the heat-sink lead frame 106 exposed through the molding 128 according to an aspect. FIG. 1I illustrates a bottom view of the semiconductor package 100 depicting portions of the lead frame 104 exposed through the molding 128 according to an aspect. FIG. 1J illustrates a side view of the semiconductor package 100 according to an aspect.

In some examples, the semiconductor package 100 is a flat no-leads package. In some examples, the semiconductor package 100 is a quad flat non-leaded (QFN) package. In some examples, the semiconductor package 100 is a dual-flat no-leads (DFN) semiconductor package 100. However, the semiconductor package 100 may incorporate any type of surface-mount technology including leaded or non-leaded packages. The semiconductor die 102 includes a semiconducting material (e.g., a silicon material) on which one or more electrical circuit are fabricated. The semiconductor die 102 may include one or more transistors (e.g., bipolar junction transistor, field-effect transistor, a metal-oxide-semiconductor field-effect transistor (MOSFET)). The semiconductor die 102 may include one or more integrated circuits (ICs).

The semiconductor die 102 includes a first surface 101 and a second surface 103. The distance between the first surface 101 and the second surface 103 may define a thickness of the semiconductor die 102 in a direction A1. The first surface 101 of the semiconductor die 102 is disposed in a plane A4. The second surface 103 may be disposed in parallel with the first surface 101. The direction A1 is aligned perpendicular to the plane A4, and a direction A2 is perpendicular to the direction A1. A direction A3 into the page (shown as a dot) is aligned parallel to the plane A4 and is orthogonal to directions A1 and A2. The directions A1, A2, and A3, and plane A4, are used throughout several of the various views of the implementations described throughout the figures for simplicity.

The lead frame 104 includes a first surface 121 and a second surface 123 disposed opposite to the first surface 121. The distance between the first surface 121 and the second surface 123 may define a thickness of the lead frame 104 in the direction A1. In some examples, referring to FIG. 1F, the lead frame 104 includes a first side 160, a second side 162, a third side 164, and a fourth side 166. The distance between the first side 160 and the third side 164 may define a width of the lead frame 104 in the direction A2, and the distance between the second side 162 and the fourth side 166 may define a length of the lead frame 104 in the direction A3. In some examples, the lead frame 104 has a rectangular shape.

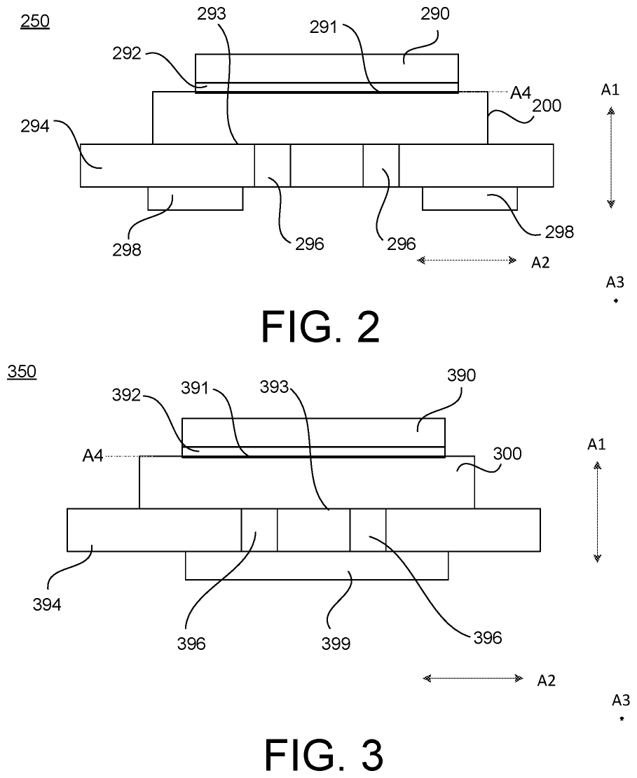

The lead frame 104 may be a conductive (metal) frame in which the semiconductor die 102 is attached. In some examples, the lead frame 104 is a copper metal frame. The second surface 103 of the semiconductor die 102 is coupled to the first surface 121 of the lead frame 104. In some examples, the second surface 123 of the lead frame 104 is coupled to a substrate (e.g., a printed circuit board (PCB) (not shown in FIGS. 1B through 1J but shown in FIGS. 2 and 3). In the orientation of FIG. 1B, the second surface 103 may be referred to as the bottom surface of the semiconductor die 102.

In some examples, the lead frame 104 is coupled to the second surface 103 of the semiconductor die 102 using die attach material 108 (e.g., a die attach film). The die attach material 108 may include an adhesive layer, solder-based material, or other types of bonding material that can couple the semiconductor die 102 to the lead frame 104. In some examples, the semiconductor package 100 includes bond wires 124 coupled to the first surface 101 of the semiconductor die 102 and the lead frame 104. The bond wires 124 may be conductive (e.g., metal) wires such as aluminum, copper, or gold, or any combination thereof, for example. In some examples, the semiconductor package 100 does not include bond wires 124. In some examples, the semiconductor die 102 is coupled to the lead frame 104 in a flip-chip configuration. For example, the semiconductor die 102 is coupled to the lead frame 104 using bump members (e.g., copper pillars) with an underfill material that encompasses the bump members.

The lead frame 104 may include a die paddle 120, leads 118, and first tie bars 130. The die paddle 120 may be a central region of the lead frame 104, and the mounting area in which the semiconductor die 102 is attached. Referring to FIG. 1F, the die paddle 120 may include a first side 161, a second side 163, a third side 165, and a fourth side 167. The distance between the first side 161 and the third side 165 may define a width of the die paddle 120 in the direction A2, and the distance between the second side 163 and the fourth side 167 may define a length of the die paddle 120 in the direction A3. In some examples, the die paddle 120 includes a rectangular shape.

The semiconductor die 102 is coupled to the die paddle 120. In some examples, the semiconductor die 102 is coupled to the die paddle 120 via the die attach material 108. In some examples, the leads 118 are metal pads. The leads 118 are formed around the die paddle 120. The leads 118 are arranged on each side of the lead frame 104. In some examples, the leads 118 are disposed apart from the die paddle 120. In some examples, the bond wires 124 are connected to the leads 118 and the semiconductor die 102. In some examples, each bond wire 124 is connected to a separate lead 118 and peripheral portions 127 at the first surface 101 of the semiconductor die 102.

As shown in FIG. 1F, the first tie bars 130 may extend from corner portions 141 of the die paddle 120. In some examples, the first tie bars 130 extend at an angle (e.g., non-zero angle, non-perpendicular angle) with respect to a central axis 133 of the lead frame 104. The central axis 133 may extend in the direction A3 and may divide the lead frame 104 into two equal halves. In some examples, the first tie bars 130 include four tie bars. In some examples, the first tie bars 130 include less than four tie bars such as two tie bars. Each of the first tie bars 130 includes an extending member 142 that extends from a respective corner portion 141 of the die paddle 120, and an end portion 144 that extends from the extending member 142.

In some examples, the lead frame 104 is flat or substantially flat. For example, the die paddle 120, the leads 118, and the first tie bars 130 may be aligned with each other and extend in the same plane. In some examples, the die paddle 120, the leads 118, and/or the first tie bars 130 are offset with respect to each other in the direction Al.

As shown in FIG. 1I (which depicts a bottom view of the semiconductor package 100), portions of the second surface 123 of the lead frame 104 are exposed outside of the molding 128—which may be referred to as a bottom exposed conductive pad. The bottom exposed conductive pad is configured to be coupled to a substrate (e.g., PCB substrate). In some examples, one or more portions of the die paddle 120 are exposed outside of the molding 128. In some examples, the bottom surface (or a portion thereof) of the die paddle 120 is exposed outside of the molding 128. Also, portions of the leads 118 are exposed outside of the molding 128 on the bottom side of the semiconductor package 100.

The heat-sink lead frame 106 may be coupled to the first surface 101 of the semiconductor die 102. With respect to the orientation of FIG. 1B, the first surface 101 may be the top surface of the semiconductor die 102. The heat-sink lead frame 106 is a metal-based structure (e.g., copper) formed from a lead frame. In some examples, the heat-sink lead frame 106 has a structure modified from the structure of the lead frame 104. The heat-sink lead frame 106 has one or more portions that are down-set from other portions of the heat-sink lead frame 106 in order to create spaces 125 for the bond wires 124 and/or provide structural reliability for the semiconductor package 100. The heat-sink lead frame 106 has a structure that extends in the direction Al from a portion that contacts the first surface 101 at a central region 129 of the semiconductor die 102 to a portion 109 that is exposed outside of the molding 128. The structure of the heat-sink lead frame 106 provides one or more spaces 125 (between the heat-sink lead frame 106 and the lead frame 104) to couple the bond wires 124 to the leads 118 and to the peripheral portions 127 on the first surface 101 of the semiconductor die 102.

In some examples, the molding 128 includes an inorganic material. In some examples, the molding 128 includes an organic material. In some examples, the molding 128 includes a combination of one or more organic materials and/or one or more inorganic materials. In some examples, the molding 128 includes an epoxy material formed from epoxy resins. In some examples, the molding 128 includes a gel material (e.g., silicone gel).

The heat-sink lead frame 106 may include an upper ring pad 110, a central contact pad 112, connecting members 114 connecting the upper ring pad 110 to the central contact pad 112, and second tie bars 126. In some examples, in contrast to the lead frame 104, the heat-sink lead frame 106 may be devoid of leads (e.g., devoid of the leads 118 of the lead frame 104). The central contact pad 112 is coupled to the first surface 101 at the central region 129 of the semiconductor die 102. The central contact pad 112 may have a size that is smaller than the size of the semiconductor die 102. In some examples, the central contact pad 112 has a rectangular shape.

The central contact pad 112 may be a central portion of the heat-sink lead frame 106 that is down-set from the upper ring pad 110 in the direction Al. For example, the upper ring pad 110 is disposed in a plane different from the plane having the central contact pad 112 in the direction Al.

Referring to FIG. 1E, the upper ring pad 110 may include a first side 170, a second side 172, a third side 174, and a fourth side 176. The distance between the first side 170 and the third side 174 may define a width of the upper ring pad 110 in the direction A2, and the distance between the second side 172 and the fourth side 176 may define a length of the upper ring pad 110 in the direction A3. In some examples, the upper ring pad 110 has a rectangular shape with four sides. As shown in FIG. 1D, the upper ring pad 110 has a first surface 151 and a second surface 153 opposite to the first surface 151. The distance between the first surface 151 and the second surface 153 may define a thickness of the upper ring pad 110 in the direction A1. At least a portion of the first surface 151 is exposed outside of the molding 128. In some examples, the entire first surface 151 is exposed outside of the molding 128. As shown in FIGS. 1F and 1G, the first surface 151 of the upper ring pad 110 is exposed through the molding 128. The exposed upper ring pad 110 may be considered a top exposed conductive pad. The top exposed conductive pad may be configured to be coupled to a heat sink (on the top side of the semiconductor package 100) in order to increase the thermal dissipation capability of the semiconductor package 100.

As shown in FIGS. 1A-1B, the upper ring pad 110 has an inner sidewall 115 (extending in the direction Al) and an outer sidewall 116 (extending in the direction A1). The inner sidewall 115 defines a central opening 111. Each of the connecting members 114 are coupled to (and extend from) the central contact pad 112 and the upper ring pad 110. In some examples, the connecting members 114 are coupled to the inner sidewall 115 of the upper ring pad 110 and to a sidewall 113 of the central contact pad 112. In some examples, the connecting members 114 are disposed at an angle (e.g., a non-zero angle) with respect to the plane A4.

As shown in FIG. 1E, the second tie bars 126 may extend from corner portions 131 of the upper ring pad 110. In some examples, the second tie bars 126 extend at an angle (e.g., non-zero angle, non-perpendicular angle) with respect to a central axis 135 of the heat-sink lead frame 106. The central axis 135 extends in the direction A3 and divides the heat-sink lead frame 106 into two equal halves. In some examples, the second tie bars 126 include four tie bars. In some examples, the second tie bars 126 include less than four tie bars such as two tie bars. Each of the second tie bars 126 includes an extending member 132 that extends from a respective corner portion 131 of the upper ring pad 110, and an end portion 134 that extends from the extending member 132.

The second tie bars 126 of the heat-sink lead frame 106 are coupled to the first tie bars 130 of the lead frame 104. For example, the end portions 134 of the second tie bars 126 are coupled to the end portions 144 of the first tie bars 130. The end portions 134 of the second tie bars 126 are down set (from the upper ring pad 110 in the direction A1) and contact the end portions 144 of the first tie bars 130. In some examples, with respect to a particular second tie bar 126, the extending member 132 is disposed at an angle (e.g., non-zero, non-perpendicular) with respect to the end portion 134. In some examples, the extending member 132 extend from the outer sidewall 116 of the upper ring pad 110. The extending member 132 extends in the direction A1 (as well as the direction A1 or A3) towards the lead frame 104.

FIG. 2 illustrates a semiconductor product 250 according to an aspect. The semiconductor product 250 includes a semiconductor package 200, a heat sink 290, a substrate 294, and one or more components 298. The semiconductor package 200 may be the semiconductor package 10 of FIG. 1A and/or the semiconductor package 100 of FIGS. 1B through 1J and may include any of the features discussed herein. The semiconductor package 200 includes a first surface 291 (e.g., where the first surface 291 includes, referring to FIGS. 1B through 1J, the first surface 151 of the upper ring pad 110 that is exposed outside of the molding 128 on the top side of the semiconductor die 102), and a second surface 293 (e.g., where the second surface 293 includes, referring to FIGS. 1B through 1J, the second surface 123 of the lead frame 104 that is exposed outside of the molding 128 on the bottom side the semiconductor die 102). The first surface 291 of the semiconductor package 200 is disposed in a plane A4. The second surface 293 may be disposed in parallel with the first surface 291. A direction Al is aligned perpendicular to the plane A4, and a direction A2 is perpendicular to the direction A1. A direction A3 into the page (shown as a dot) is aligned parallel to the plane A4 and is orthogonal to directions A1 and A2.

The first surface 291 of the semiconductor package 200 is coupled to the heat sink 290. In some examples, the first surface 291 is coupled to the heat sink 290 via a thermal layer 292. For example, the top of the semiconductor package 200 is connected to the heat sink 290 to enhance top-side cooling of the semiconductor package 200. For example, the exposed connection pad on the top-side of the semiconductor package 200 (e.g., the first surface 151 of the upper ring pad 110 that is exposed outside of the molding 128 on the top side of the semiconductor die 102) is coupled to the heat sink 290. In some examples, the thermal layer 292 is a thermal gel or paste. In some examples, the heat sink 290 is a conductive metal structure (e.g., copper or aluminum) that is configured to dissipate heat generated by the semiconductor package 200. In some examples, the heat sink 290 is a portion of a metal enclosure.

The second surface 293 of the semiconductor package 200 is coupled to a substrate 294. The substrate 294 may include a base material (e.g., a dielectric material). In some examples, the substrate 294 is a printed circuit board (PCB) substrate. In some examples, the substrate 294 includes conductive traces on one or both surfaces of (or embedded within) the substrate 294. Also, one or more components 298 may be coupled to the substrate 294. In some examples, the components 298 include transistors, integrated circuits, drivers, redistribution layers, etc. In some examples, the substrate 294 includes one or more thermal vias 296. The thermal vias 296 may be conducted filled or plated holes that extend through the substrate 294 in the direction Al. The thermal vias 296 may enhance bottom side cooling of the semiconductor package 200. For example, the exposed connection pad on the bottom side of the semiconductor package 200 (e.g., the second surface 123 of the lead frame 104 that is exposed outside of the molding 128 on the bottom side the semiconductor die 102) is coupled to the thermal vias 296 of the substrate 294 to enhance bottom side cooling of the semiconductor package 200.

FIG. 3 illustrates a semiconductor product 350 according to an aspect. The semiconductor product 350 may be similar to the semiconductor product 250 of FIG. 2 and may include any of the features discussed herein. For example, the semiconductor product 350 includes a semiconductor package 300, a first heat sink 390, a substrate 394, and a second heat sink 399. The semiconductor package 300 may be the semiconductor package 10 of FIG. 1A and/or the semiconductor package 100 of FIGS. 1B through 1J and may include any of the features discussed herein. The semiconductor package 300 includes a first surface 391 (e.g., where the first surface 391 includes, referring to FIGS. 1B through 1J, the first surface 151 of the upper ring pad 110 that is exposed outside of the molding 128 on the top side of the semiconductor die 102), and a second surface 393 (e.g., where the second surface 293 includes, referring to FIGS. 1B through 1J, the second surface 123 of the lead frame 104 that is exposed outside of the molding 128 on the bottom side the semiconductor die 102). The first surface 391 of the semiconductor package 300 is disposed in a plane A4. The second surface 393 may be disposed in parallel with the first surface 391. A direction A1 is aligned perpendicular to the plane A4, and a direction A2 is perpendicular to the direction A1. A direction A3 into the page (shown as a dot) is aligned parallel to the plane A4 and is orthogonal to directions A1 and A2.

The first surface 391 of the semiconductor package 300 is coupled to the first heat sink 390. In some examples, the first surface 391 is coupled to the first heat sink 390 via a thermal layer 392. In some examples, the thermal layer 392 is a thermal gel or paste. In some examples, the first heat sink 390 is a conductive metal structure (e.g., copper or aluminum) that is configured to dissipate heat generated by the semiconductor package 300. In some examples, the first heat sink 390 is a portion of a metal enclosure.

The second surface 393 of the semiconductor package 300 is coupled to a substrate 394. The substrate 394 may include a base material (e.g., a dielectric material). In some examples, the substrate 394 is a printed circuit board (PCB) substrate. In some examples, the substrate 394 includes conductive traces on one or both surfaces of (or embedded within) the substrate 394. In some examples, the substrate 394 includes one or more thermal vias 396. The thermal vias 396 may be conducted filled or plated holes that extend through the substrate 394 in the direction Al. The thermal vias 396 may enhance bottom side cooling of the semiconductor package 300. The second heat sink 399 may be coupled to the substrate 394 (e.g., coupled to the thermal vias 396 of the substrate 394) to further enhance bottom-side cooling of the semiconductor package 300. In some examples, the second heat sink 399 is a conductive metal structure (e.g., copper or aluminum) that is configured to dissipate heat generated by the semiconductor package 300. In some examples, the second heat sink 399 is a portion of a metal enclosure.

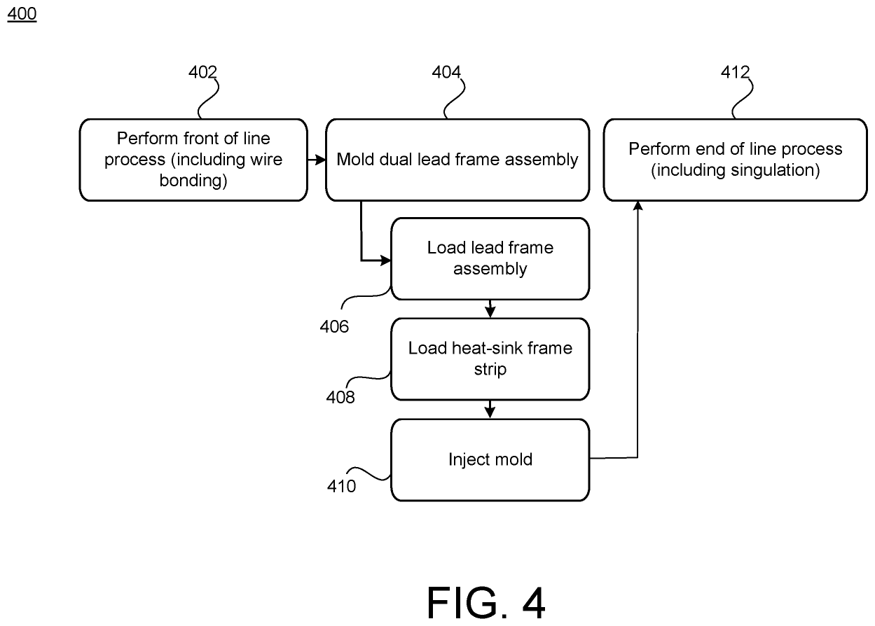

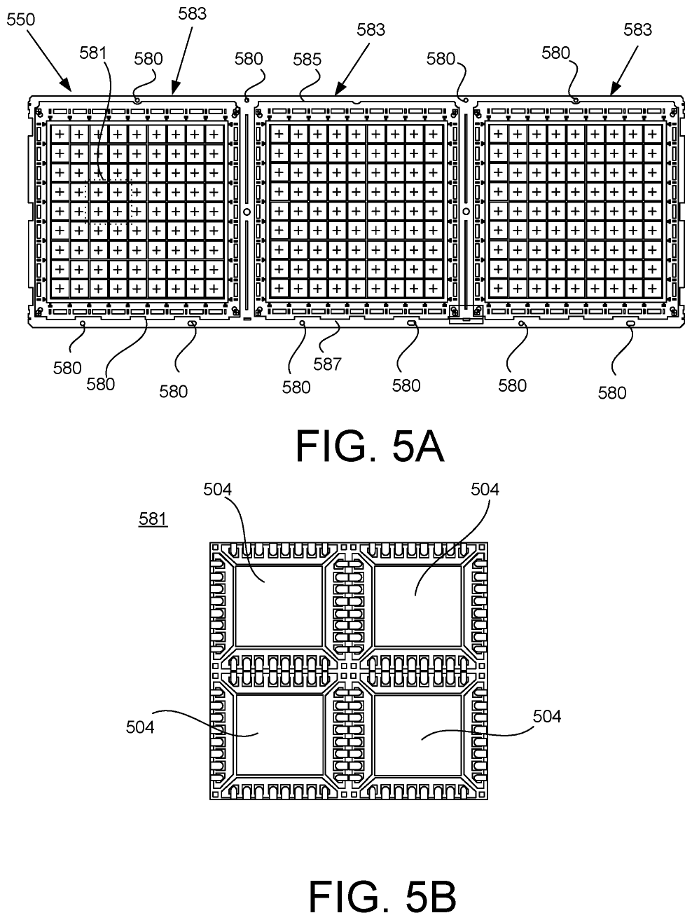

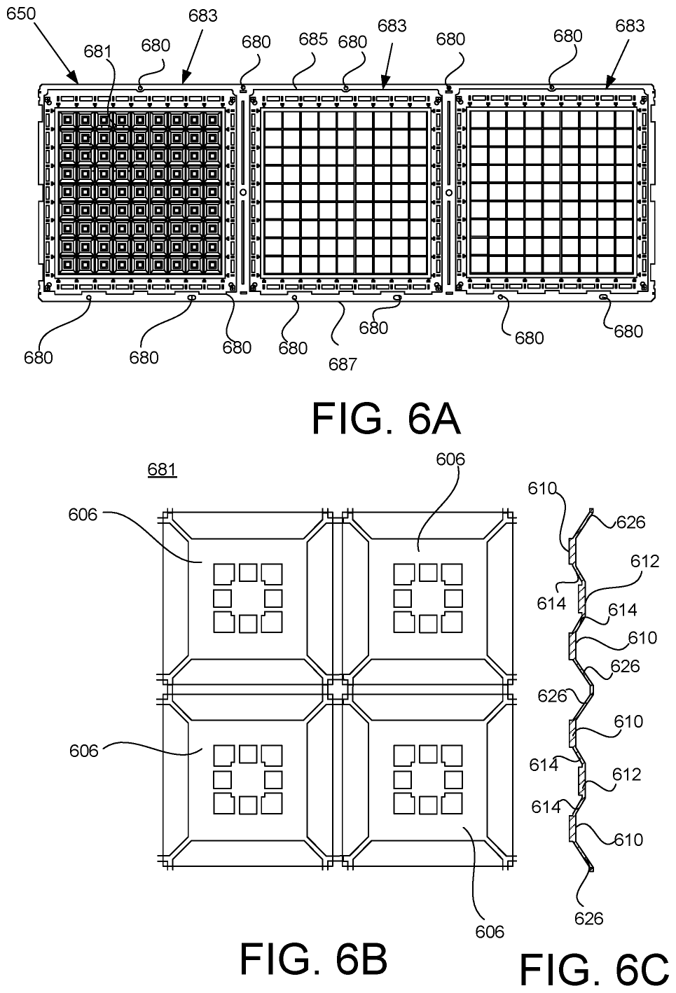

FIG. 4 illustrates a process flow 400 for manufacturing semiconductor packages according to an aspect. For example, the process flow 400 relates to forming semiconductor packages having a dual lead frame, which may be formed from a lead frame strip (e.g., the lead frame strip 550 of FIGS. 5A and 5B), and a heat-sink lead frame strip (e.g., the heat-sink lead frame strip 650 of FIGS. 6A through 6C). The lead frame strip may define a plurality of individual lead frames (e.g., one of which is the lead frame 104 of FIGS. 1B through 1J). The heat-sink lead frame strip may define a plurality of individual heat-sink lead frames (e.g., one of which is the heat-sink lead frame 106 of FIGS. 1B through 1J).

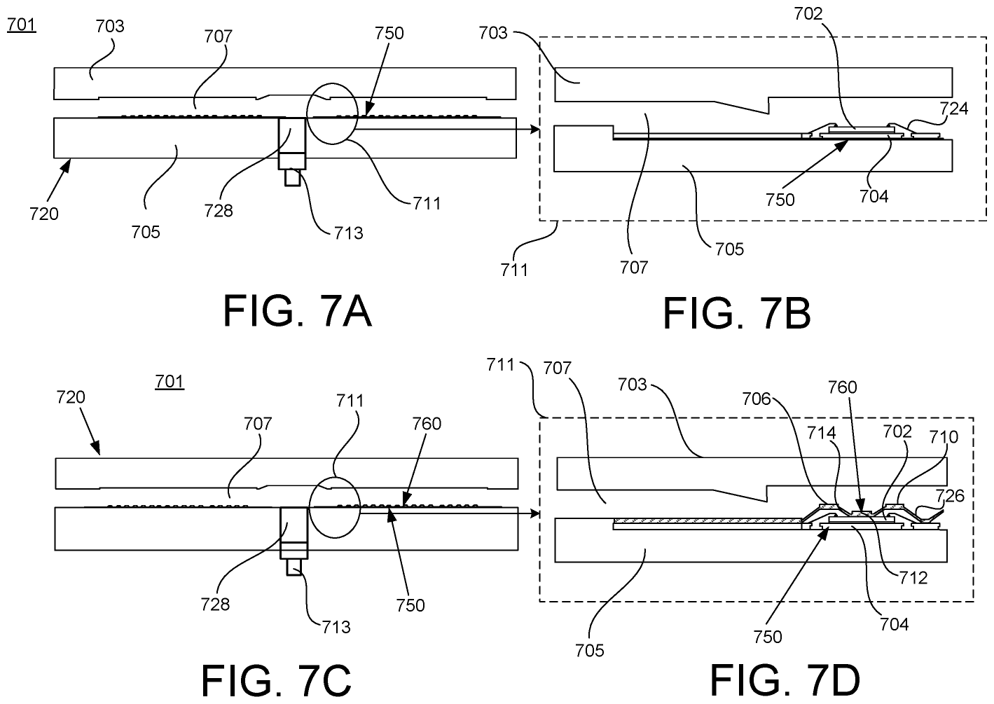

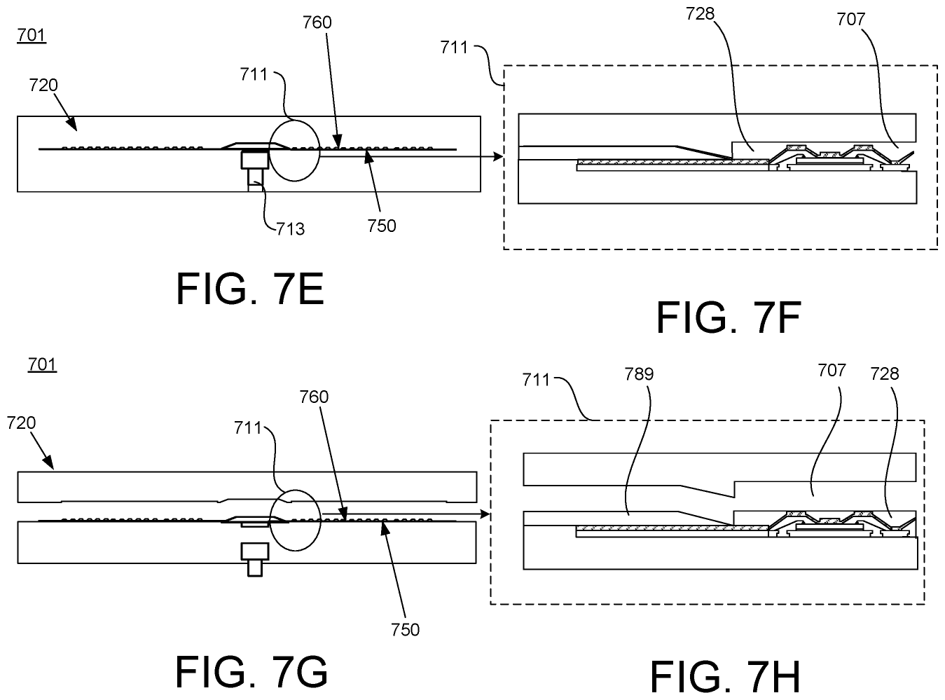

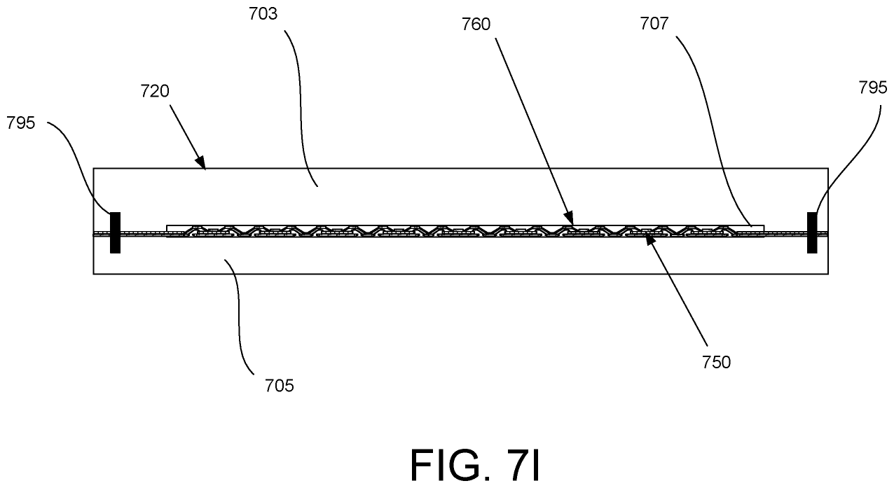

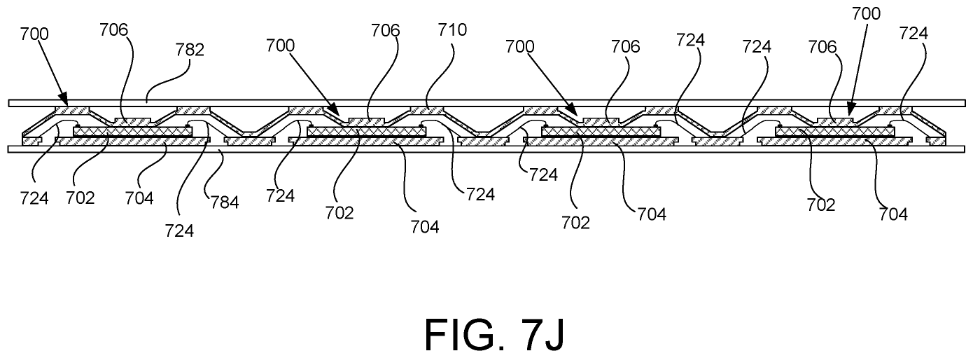

In operation 402, front of line process (including wire bonding) is performed. For example, the operation 402 may include attaching semiconductor dice (e.g., the semiconductor die 102 of FIGS. 1B through 1J) to the lead frame strip, and attaching bond wires (e.g., the bond wires 124 of FIGS. 1B through 1J) to the semiconductor dice and the lead frame strip, thereby forming a lead frame assembly. In operation 404, the dual lead frame assembly is molded. For example, in operation 406, the lead frame assembly (with the semiconductor dice and bond wires attached to the lead frame strip) are loaded into a cavity of a mold chase of a molding tool. In operation 408, the heat-sink lead frame strip is loaded on top of the lead frame assembly within the cavity of the mold chase. In operation 410, the molding is injected into the cavity of the mold chase. The details of operations 406, 408, and 410 are further explained with reference to FIGS. 7A through 7H. In operation 412, end of line process (including singulation) is performed. For example, the mold runners may be removed, and the molded dual lead frame assembly may be cut into their individual packages (e.g., one of which is the semiconductor package 100 of FIGS. 1B through 1J).

FIG. 5A illustrates a lead frame strip 550 used for manufacturing semiconductor packages according to an aspect. The lead frame strip 550 may be considered a first strip of the dual strip. In some examples, the lead frame strip 550 is a mold array process (MAP) assembly defining a plurality of MAPs 583. Each MAP 583 defines individual lead frames 504. In the example of FIG. 5A, each MAP 583 defines an arrangement of nine by nine lead frames 504, however the MAP 583 may define any number of individual lead frames 504. A single lead frame 504 corresponds to the lead frame 104 of FIGS. 1B through 1J. FIG. 5B illustrates an enlarged view of a portion 581 of the lead frame strip 550, e.g., depicting four individual lead frames 504.

The lead frame strip 550 defines locator holes 580. The locator holes 580 are defined on a first side 585 and a second side 587 of the lead frame strip 550. As discussed later in the disclosure, when the lead frame assembly having the lead frame strip 550 is placed in a cavity of a mold chase of a molding tool, the locator holes 580 receive alignment pins (defined on the mold chase) in order to properly align the lead frame assembly within the mold chase.

FIG. 6A illustrates a heat-sink lead frame strip 660 used for the manufacturing of semiconductor packages according to an aspect. The heat-sink lead frame strip 660 may be considered the second strip. A lead frame strip (e.g., one that is similar or the same as the lead frame strip 550) may be chemically etched or mechanically punched to create the heat-sink lead frame strip 660. In some examples, the heat-sink lead frame strip 660 is a MAP assembly defining a plurality of MAPs 683. Each MAP 683 defines individual heat-sink lead frames 606. In the example of FIG. 6A, each MAP 683 defines an arrangement of nine by nine heat-sink lead frames 606, however, the MAPs 683 may define any number of heat-sink lead frames 606. A single heat-sink lead frame 606 corresponds to the heat-sink lead frame 106 of FIGS. 1B through 1J. FIG. 6B illustrates an enlarged top view of a portion 681 of the heat-sink lead frame strip 660, e.g., depicting four individual heat-sink lead frames 606. FIG. 6C illustrates a side view of the portion 681 of the heat-sink lead frame strip 660 according to an aspect.

The heat-sink lead frame strip 660 defines locator holes 680. The locator holes 680 are defined on a first side 685 and a second side 687 of the heat-sink lead frame strip 660. As discussed later in the disclosure, when the heat-sink lead frame strip 660 is placed on top of the lead frame assembly having the lead frame strip 550 of FIG. 5A within the cavity of the mold chase, the locator holes 680 receive alignment pins (defined on the mold chase) in order to properly align the heat-sink lead frame strip 660 with respect to the lead frame strip 550 within the mold chase. Each heat-sink lead frame 606 may include any of the features described with reference to the previous figures. Each heat-sink lead frame 606 includes an upper ring pad 610, a central contact pad 612, connecting members 614, and tie bars 626. As shown in FIG. 6B and 6C, tie bars 626 from one heat-sink lead frame 606 is connected to tie bars 626 from an adjacent heat-sink lead frame 606.

FIGS. 7A through 7J illustrates various aspects of the manufacturing process of FIG. 4 according to an aspect. As discussed with reference to these figures, the dual lead frame assembly is loaded into a mold tool 701 and a molding 728 is injected to mold the dual lead frame assembly. As shown in FIG. 7I, the mold chase 720 includes alignment pins 795 configured to receive locator holes (e.g., the locator holes 580 of FIG. 5A, the locator holes 680 of FIG. 6A) in order to properly align the dual lead frame strips. The mold tool 701 includes a mold injector 713 configured to inject a molding 728 into a mold chase 720. The mold chase 720 includes a top mold chase component 703 and a bottom mold chase component 705.

In FIG. 7A, after the front of the line process is performed (e.g., operation 404 of FIG. 4), the mold chase 720 is open (e.g., the top mold chase component 703 is moved away from the bottom mold chase component 705), and a lead frame assembly 750 is disposed in a cavity 707 of the mold chase 720 (e.g., see operation 406 of FIG. 4). For example, the locator holes (e.g. the locator holes 580 of FIG. 5A) of the lead frame assembly 750 receive the alignment pins 795 in order to place the lead frame assembly 750 in the proper position within the mold chase 720. In some examples, the lead frame assembly 750 includes the lead frame strip 550 of FIGS. 5A and 5B with semiconductor dice and bond wires coupled to the lead frame strip 550 of FIGS. 5A and 5B.

FIG. 7B illustrates an enlarged view of a portion 711 of the mold chase 720 depicting a portion of the lead frame assembly 750. For example, as discussed with reference to the previous figures, the lead frame assembly 750 includes a lead frame 704, a semiconductor die 702 coupled to the lead frame 704, and bond wires 724 connected to the semiconductor die 702 and the lead frame 704. The lead frame 704, the semiconductor die 702, and the lead frame 704 may be the same as the lead frame 104, the semiconductor die 102, and the bond wires 124 of FIGS. 1B through 1J and may include any of the details discuss herein.

In FIG. 7C, a heat-sink lead frame strip 760 is loaded into the mold chase 720, and place on top of the lead frame assembly 750 (e.g., see operation 408 of FIG. 4). For example, the locator holes (e.g. the locator holes 680 of FIG. 6A) of the heat-sink lead frame strip 760 receive the alignment pins 795 of the mold chase 720 in order to properly align the heat-sink lead frame strip 760 with respect to the lead frame assembly 750. FIG. 7D illustrates an enlarged view of the portion 711 of the mold chase 720 depicting a portion of the heat-sink lead frame strip 760 stacked on top of the lead frame assembly 750. For example, as shown with respect to FIG. 7D, the heat-sink lead frame strip 760 includes a heat-sink lead frame 706 having an upper ring pad 710, a central contact pad 712, connecting members 714, and tie bars 726. The heat-sink lead frame 706 may be the heat-sink lead frame 106 of FIGS. 1B through 1J and may include any of the features discussed herein.

FIG. 7J illustrates a side view of a perspective of the dual frame assembly that may be loaded into the mold chase 720 (e.g., as shown in FIG. 7D). For example, FIG. 7J depicts a series of individual units 700, where each unit 700 is included within a separate semiconductor package (e.g., the semiconductor package 100 of FIGS. 1B through 1J). For example, each unit 700 includes a lead frame 704, a semiconductor die 702 coupled to the lead frame 704, bond wires 724 coupled to the lead frame 704 and the semiconductor die 702, and a heat-sink lead frame 706. As shown in FIG. 7J, a first adhesive layer 782 is coupled to a top of the units 700, and a second adhesive layer 784 is coupled to a bottom of the units 700. In some examples, the second adhesive layer 784 is used to prevent mold flash on the bottom of the lead frame 704. In some examples, the first adhesive layer 782 is used to prevent mold flash on the upper ring pad 710.

In FIG. 7E, the mold chase 720 is closed, and the mold injector 713 injects the mold 728 into the cavity 707 of the mold chase (e.g., see operation 410 of FIG. 4). In some examples, the bottom mold chase component 705 is modified (from a conventional mold chase) to accommodate for the thickness of the two strips and the thickness of the first adhesive layer 782 (and/or the thickness of the second adhesive layer 784). For example, the cavity depth of the bottom chase component 705 may be increased to allow for twice the lead frame thickness as well as the first adhesive layer 782 and/or the second adhesive layer 784. FIG. 7F illustrates an enlarged view of the portion 711 of the mold chase 720 depicting the mold 728 applied to the dual frame assembly. In FIG. 7G, the mold chase 720 is opened, leaving the molded dual frame assembly. FIG. 7H illustrates an enlarged view of the portion 711 of the mold chase 720 depicting the molded dual frame assembly along with a mold runner 789 (which is removed at a later manufacturing step).

It will be understood that, in the foregoing description, when an element is referred to as being connected to, electrically connected to, coupled to, or electrically coupled to another element, it may be directly connected or coupled to the other element, or one or more intervening elements may be present. In contrast, when an element is referred to as being directly connected to or directly coupled to another element, there are no intervening elements. Although the terms directly connected to, or directly coupled to may not be used throughout the detailed description, elements that are shown as being directly connected or directly coupled can be referred to as such. The claims of the application, if any, may be amended to recite exemplary relationships described in the specification or shown in the figures. Implementations of the various techniques described herein may be implemented in (e.g., included in) digital electronic circuitry, or in computer hardware, firmware, software, or in combinations of them. Portions of methods also may be performed by, and an apparatus may be implemented as, special purpose logic circuitry, e.g., an FPGA (field programmable gate array) or an ASIC (application specific integrated circuit).

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. A semiconductor package comprising:
a semiconductor die having a first surface and a second surface opposite to the first surface;
a lead frame coupled to the second surface of the semiconductor die; and
a heat-sink lead frame coupled to the first surface of the semiconductor die, the semiconductor die being disposed between the lead frame and the heat-sink lead frame, the heat-sink lead frame configured to transfer heat away from the semiconductor die.

2. The semiconductor package of claim 1, wherein the heat-sink lead frame includes a plurality of tie bars connected to the lead frame.

3. The semiconductor package of claim 1, further comprising:
a molding encapsulating the semiconductor die, at least a portion of the heat-sink lead frame being exposed outside of the molding.

4. The semiconductor package of claim 1, wherein the lead frame includes a die paddle and a plurality of leads configured to connect with an external device, the heat-sink lead frame being devoid of leads.

5. The semiconductor package of claim 1, further comprising:
a first adhesive layer coupled to the lead frame; and
a second adhesive layer coupled to the heat-sink lead frame.

6. The semiconductor package of claim 1, wherein the heat-sink lead frame includes an upper ring pad, a central contact pad, and a plurality of connecting members connecting the upper ring pad to the central contact pad.

7. The semiconductor package of claim 6, wherein the central contact pad is coupled to the first surface of the semiconductor die.

8. The semiconductor package of claim 6, wherein the upper ring pad is disposed in a first plane and the central contact is disposed in a second plane, the first plane being disposed a distance away from the second plane, the plurality of connecting members extending between the first plane and the second plane.

9. The semiconductor package of claim 6, wherein the upper ring pad has a sidewall defining an opening, the plurality of connecting members being coupled to the sidewall.

10. The semiconductor package of claim 6, wherein the heat-sink lead frame includes a first tie bar extending from a first corner portion of the upper ring pad, and a second tie bar extending from a second corner portion of the upper ring pad.

11. A semiconductor package comprising:
a semiconductor die having a first surface and a second surface opposite to the first surface;
a lead frame coupled to the second surface of the semiconductor die, the lead frame including a plurality of leads and a plurality of first tie bars, the plurality of leads configured to connect to an external device; and
a heat-sink lead frame coupled to the first surface of the semiconductor die, the heat-sink lead frame including a plurality of second tie bars, the plurality of second tie bars coupled to the plurality of first tie bars, the heat-sink lead frame configured to transfer heat way from the semiconductor die.

12. The semiconductor package of claim 11, wherein the heat-sink lead frame includes an upper ring pad, a central contact pad, and a plurality of connecting members connecting the upper ring pad to the central contact pad, the central contact pad being coupled to the first surface of the semiconductor die.

13. The semiconductor package of claim 12, wherein the upper ring pad is disposed in a first plane and the central contact pad is disposed in a second plane, the first plane being disposed a distance away from the second plane, the plurality of connecting members extending between the first plane and the second plane.

14. The semiconductor package of claim 12, wherein the upper ring pad has a sidewall defining an opening, the plurality of connecting members being coupled to the sidewall.

15. The semiconductor package of claim 12, further comprising:
a molding encapsulating the central contact pad and the plurality of connecting member, at least a portion of the upper ring pad being exposed through the molding, at least a portion of the lead frame being exposed through the molding.

16. The semiconductor package of claim 12, wherein the lead frame includes a die paddle coupled to the semiconductor die, the die paddle having has a size that is substantially the same as a size of the upper ring contact.

17. The semiconductor package of claim 11, further comprising:
a bond wire having a first end portion and a second end portion, the first end portion of the bond wire being connected to one of the plurality of leads of the lead frame, the second end portion of the bond wire being connected to the first surface of the semiconductor die.

18. The semiconductor package of claim 11, wherein the semiconductor die is connected to the lead frame in a flip-chip configuration.

19. A method of fabricating a semiconductor package having dual lead frames, the method comprising:
disposing a lead frame assembly in a cavity of a mold chase, the lead frame assembly including a lead frame strip having a lead frame, the lead frame assembly including a semiconductor die having a first surface coupled to the lead frame;
disposing a heat-sink lead frame strip in the cavity of the mold chase, the heat-sink lead frame strip including a heat-sink lead frame having an upper ring pad, a central contact pad, and a plurality of connecting members connecting the upper ring pad to the central contact pad; and
injecting a molding material into the cavity of the mold tool.

20. The method of claim 19, wherein at least a portion of the upper ring pad is exposed through the molding, at least a portion of the first lead frame is exposed through the molding.
